(19) United States
(12) Patent Application Publication
(10) Pub. No.: US 2025/0257813 A1
(43) Pub. Date: Aug. 14, 2025

(54) FLUID CONTROL VALVE

(71) Applicant: CKD CORPORATION, Komaki-shi, Aichi (JP)

(72) Inventors: Junichi BITO, Komaki-shi (JP); Akihiro MORI, Sakura-shi (JP); Minoru TAKAHATA, Sakura-shi (JP)

(73) Assignee: CKD CORPORATION, Komaki-shi, Aichi (JP)

(21) Appl. No.: 18/857,133

(22) PCT Filed: Sep. 26, 2023
(86) PCT No.: PCT/JP2023/034904

§ 371 Date: Oct. 15, 2024

(30) Foreign Application Priority Data
Oct. 13, 2022 (JP) 2022-164702

(51) Int. Cl. F16K 31/04; F16K 7/12; F16K 37/00; G05D 7/06

(52) U.S. Cl. CPC F16K 31/046; F16K 7/12; F16K 37/0041; G05D 7/0635

(57) ABSTRACT

The present invention has: a valve body; a servo motor having a drive shaft for operating the valve body; a position control mode for controlling the drive shaft to move the drive shaft to a target position, and a thrust control mode for controlling the drive shaft to cause the drive shaft to obtain a target thrust; and a control program that, when operating the valve body from a valve open position to a valve close position, controls the servo motor in the position control mode from the valve open position until the valve body reaches a predetermined position before reaching the valve close position, and, from the predetermined position, switches the control of the servo motor from the position control mode to the thrust control mode with a target thrust of zero, and causes the valve body to reach the valve close position only by the biasing force.

### TECHNICAL FIELD

The present invention relates to a fluid control valve comprising a motor, a valve element, a valve seat, and a passage to control a control fluid flowing through the passage by operating the valve element by the motor from a valve open position, at which the valve element is separated from the valve seat, to a valve close position, at which the valve element comes to contact with the valve seat.

### BACKGROUND ART

Several types of process gases are used for film forming processing in a semiconductor manufacturing process. A fluid control valve is used for controlling each flow rate of these process gases. As fluid control valves, for example, a fluid control valve disclosed in the Patent Literature 1 has been known. The fluid control valve disclosed in the Patent Document 1 is an air-operated-type open/close valve that is to perform flow rate control of a process gas by controlling contact and separation motion of a valve element (a diaphragm) and a valve seat by an air cylinder.

Further, the fluid control valve disclosed in the Patent Document 1 is an air-operated-type open/close valve provided with an air cylinder as a driving device, but another example is to adopt an electric driving type that utilizes a linear servomotor as a driving source. When the linear servomotor is used as the driving source, for example, a position at which a valve element and a valve seat come to contact with each other is set as an origin position of the servomotor, and a valve open degree is adjusted based on a relative position from the origin position. Then, the servomotor is made to return to the origin position for valve closing, and thereby the valve element and the valve seat are brought into contact with each other.

### RELATED ART DOCUMENTS

### Patent Documents

Patent Document 1: JP-A-2017-223318

### SUMMARY OF INVENTION

### Problems to be Solved by the Invention

However, the above-mentioned fluid control valve utilizing the linear servomotor has the following problem.

Normally, arrangement of an origin position is usually made by a user of a fluid control valve under a normal temperature atmosphere. However, a process gas to be controlled is extremely hot like 200° C., for example. A valve seat is usually made of resin such as PFA, and accordingly, the valve seat is heated by the control fluid and expanded. By this expansion, a dimension of the valve seat in an opening/closing direction (a thickness dimension) of a valve element could be larger than a dimension under the normal temperature. This increase in the thickness dimension of the valve seat causes contact of the valve element and the valve seat before the servomotor reaches the origin position while the valve is to be closed from the valve open state. However, the servomotor tries to return to the origin position even after the valve element and the valve seat are contacted, which could cause strong interference of the valve element and the valve seat, resulting in high load to the servomotor. A fluid control valve performing fluid control of a process gas in a semiconductor manufacturing process needs to accurately control a valve open degree, and therefore a servomotor with high resolution is used. By this reason, only a several micrometers of expansion of the valve seat could cause significantly high load to the servomotor. Applying continuous high load to the servomotor could cause breakage in the servomotor such as burn damage of a motor coil.

Further, when the valve seat gets abraded due to repetitive contact and separation of the valve element and the valve seat, a thickness dimension of the valve seat could be smaller than that of an initial state. When the thickness dimension of the valve seat becomes smaller, there is a possibility that the valve element and the valve seat could not be contacted even if the servomotor has reached the origin position while the valve is to be closed from the valve open state. Failure in contact of the valve element and the valve seat could cause leakage of fluid by sealing failure.

The present invention has been made in view of the above problems and has a purpose of providing a fluid control valve that can be responsive to changes in a dimension of a valve seat in an opening/closing direction of a valve element.

### Means of Solving the Problems

To solve the above problem, a fluid control valve according to one aspect of the present invention has the following configuration.

(1) The fluid control valve is characterized as a fluid control valve provided with a motor, a valve element, a valve seat, and a passage, and configured to perform controlling of a control fluid to flow through the passage by moving the valve element with the motor between a valve open position at which the valve element is separated from the valve seat and a valve close position at which the valve element is contacted with the valve seat, wherein the fluid control valve is provided with an elastic member to apply an urging force to the valve element in a closing direction, the motor is provided with a drive shaft to operate the valve element, a position control mode to control the drive shaft to move to a target position and a thrust control mode to control the drive shaft to obtain a target thrust are provided, and while the valve element moves from the valve open position to the valve close position, the fluid control valve is provided with a control program configured to control the motor with the position control mode until the valve element reaches a predetermined position before reaching the valve close position from the valve open position and to switch control of the motor from the position control mode to the thrust control mode with the target thrust of zero to bring the valve element to reach the valve close position from the predetermined position only by the urging force.

According to the fluid control valve described in (1), while the valve element moves from the valve open position to the valve close position, the motor is controlled by the position control mode until the valve element reaches the predetermined position before reaching the valve close position from the valve open position, control of the motor is switched from the position control mode to the thrust control mode with the target thrust of zero from the predetermined position, and the valve element is controlled to reach the valve close position only by the urging force of the elastic member. In other words, the valve element is driven only by the urging force of the elastic member from the predetermined position to the valve close position. Accordingly, even if the valve element and the valve seat come to contact before the motor reaches the origin position due to expansion of the valve seat, the motor would not try to return to the origin position thereafter. Therefore, the motor is not subjected to the high load, and breakage of the motor such as burn damage of a motor coil can be prevented.

Further, even when the valve seat gets abraded to become smaller in size and the valve element and the valve seat fail to contact each other even after the motor has reached the origin position, the valve element is driven only by the urging force of the elastic member from the predetermined position, and thus the valve element would not stop at the origin position but is assuredly driven to the valve close position to be in contact with the valve seat. Accordingly, occurrence of fluid leakage due to sealing failure can be prevented.

(2) In the fluid control valve described in (1), preferably, the control program is configured to maintain a state in which the valve element is at the valve close position after the valve element reaches the valve close position by the thrust control mode with the target thrust of zero.

According to the fluid control valve described in (2), a case of maintaining the valve closed state, namely, a state in which the valve element is at the valve close position is maintained by the thrust control mode with the target thrust of zero. To be specific, the motor is not subjected to the load but the valve closed state is maintained only by the urging force of the elastic member. Thereby, the load applied to the motor can be reduced, and thus lifespan of the motor can be extended. Further, for example, even when the fluid control valve gets broken or power supply to the fluid control valve is shut down due to power outage and others, the valve closed state can be maintained only by the urging force of the elastic member, thereby achieving high safety in view of fail safe.

(3) In the fluid control valve described in (1) or (2), preferably, the predetermined position is determined based on a thermal expansion amount of the valve seat in an opening/closing direction of the valve element.

In order to enhance responsivity in driving the valve element from the valve open position to the valve close position, it is preferable to arrange the predetermined position as close as possible to the valve seat to reduce a range of relying only on the urging force of the elastic member between the valve open position and the valve close position as narrow as possible. Accordingly, the predetermined position is determined based on the thermal expansion amount of the valve seat in the opening/closing direction of the valve element. Specifically, for example, when the thermal expansion amount of the valve seat is Δt, the predetermined position is set at a position behind the origin position of the motor by the amount Δt and an additional several micrometers. This position is a point at which the valve element advances by 90 to 95% from the valve open position toward the closing direction during stroke of the valve element from the valve open position to the valve close position. The predetermined position is thus set so that the valve element is driven to a position directly before contacting the expanded valve seat under the position control mode of the motor, and thus the valve can be closed with high responsivity.

### Effects of the Invention

According to the fluid control valve of the present invention, the valve can respond to changes in a dimension of a valve seat in an opening/closing direction of a valve element.

### BRIEF DESCRIPTION OF THE DRAWINGS

FIG. 1 is a schematic sectional view of a fluid control valve;

FIG. 2 is a partial enlarged view of a part X in FIG. 1;

FIG. 3 is a block diagram of a control system of the fluid control valve;

FIG. 4 is a flow of an initial setting program of the fluid control valve;

FIG. 5 is a flow of a control program of the fluid control valve; and

FIG. 6 (a) is a diagram indicating a state of a control mode of a servomotor while a valve element moves from a valve open position to a valve close position, (b) is a graph indicating a position of the valve element while the valve element moves from the valve open position to the valve close position, and (c) is a graph indicating a thrust value of a drive shaft while the valve element moves from the valve open position to the valve close position.

### MODE FOR CARRYING OUT THE INVENTION

An embodiment of a fluid control valve according to the present invention is explained in detail with reference to the accompanying drawings.

### (Configuration of Fluid Control Valve)

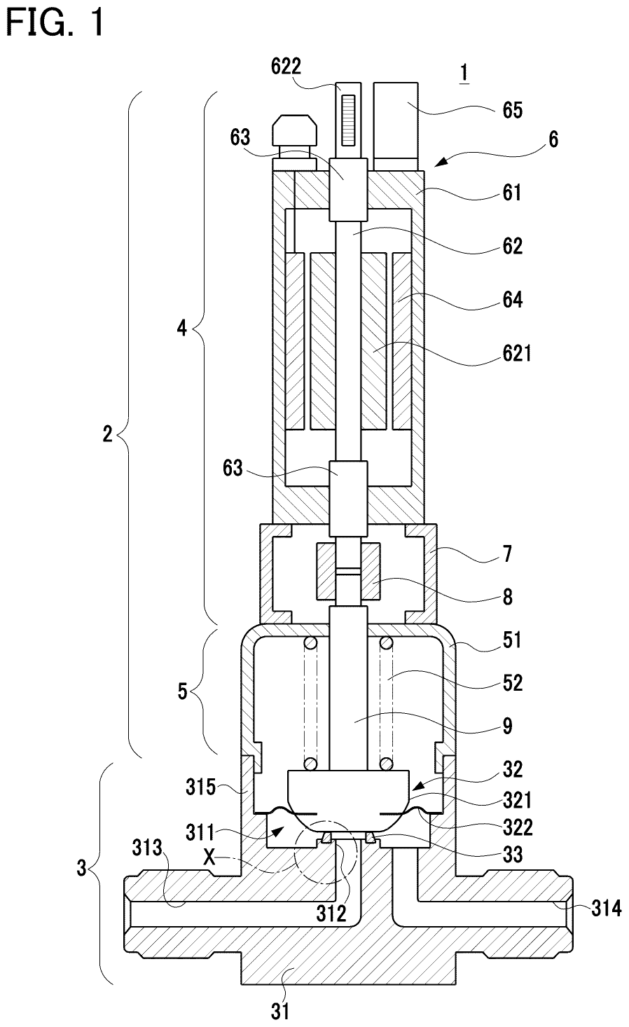

A configuration of a fluid control valve 1 according to the present embodiment is explained with reference to FIG. 1. FIG. 1 is a schematic sectional view of the fluid control valve 1. The fluid control valve 1 is an electric-motor-operated gas valve disposed in a gas supply system of a semiconductor manufacturing device and is formed of a drive unit 2 and a valve unit 3. Further, the drive unit 2 is formed of an actuator part 4 and a spring part 5.

Firstly, the actuator part 4 is explained. The actuator part 4 is provided with a direct-acting servomotor 6 (one example of a motor) and a connecting bracket 7 for connecting the servomotor 6 and the spring part 5.

The servomotor 6 is provided with a parallelepiped case 61 and a columnar drive shaft 62 that is inserted in a center portion of the case 61. The case 61 is provided with linear bearings 63 each of which is placed on an end portion (a lower end portion in the figure) on the connecting bracket 7 side and on an end portion (an upper end portion in the figure) on an opposite side from the connecting bracket 7 side. These linear bearings 63 support the drive shaft 62 to be reciprocally movable in an axial direction. The axial direction of the drive shaft 62 is an upper and lower direction in FIG. 1 and coincides with an opening/closing direction of a valve element 32 which will be explained below. Herein, an upper side in the figure represents the opening direction and a lower side represents the closing direction.

The drive shaft 62 is provided with a magnet 621 on an outer circumference in a portion that is inserted in the case 61. Further, the case 61 is provided with a coil 64 placed to surround the magnet 621 of the drive shaft 62. The magnet 621 is to be moved in the opening/closing direction corresponding to each magnitude of a voltage and a current in energization of the coil 64. Thereby, the drive shaft 62 joined to the magnet 621 is driven in the opening/closing direction.

The drive shaft 62 is provided with a linear scale 622 on the end portion (the upper end portion in the figure) on the opposite side from the connecting bracket 7 side. Further, the servomotor 6 is provided on the upper end portion of the case 61 with a linear encoder 65 to detect changes in a vertical position of the linear scale 622. The linear encoder 65 detects changes in the vertical position of the linear scale 622, and thereby the position in the opening/closing direction of the drive shaft 62 can be detected.

The end portion (the lower end portion in the figure) of the drive shaft 62 on the connecting bracket 7 side protrudes from the case 61 and is coupled with the columnar rod 9 by a coupling 8 inside the connecting bracket 7. The rod 9 is inserted in the spring part 5 and extends from an inside of the connecting bracket 7 to the valve unit 3.

Next, the spring part 5 is explained. The spring part 5 is provided with a housing 51 and a spring 52 (one example of an elastic member). The housing 51 is of a hollow shape and the rod 9 is inserted therethrough in a center portion. Then, the spring 52 is placed coaxially with the rod 9. The spring 52 is a compression coil and continuously urges the valve element 32 in the closing direction (a lower direction in the figure) by bringing its end portion (a lower end portion in the figure) on the valve unit 3 side into contact with an end face (an upper end face in the figure) of the valve element 32 on the spring 52 side, which will be explained below.

Next, the valve unit 3 is explained. The valve unit 3 is provided with a body 31 and the valve element 32. The body 31 is provided with a cylindrical portion 315 connected to the spring part 5. Further, the body 31 is perforated with a valve chamber 311 on an inside of the cylindrical portion 315.

The valve chamber 311 is communicated with an input passage 313 in its center portion through a valve port 312. This input passage 313 is used for intaking process gas to the valve chamber 311. Further, the annular valve seat 33 is provided coaxially with the valve port 312 on an outer circumferential portion of the valve port 312 on a bottom surface of the valve chamber 311. Furthermore, the valve chamber 311 is communicated with an output passage 314 on an outside in a radial direction of the valve seat 33. This output passage 314 is used for discharging the process gas from the valve chamber 311. Specifically, the input passage 313, the valve chamber 311, and the output passage 314 constitute a series of passages through which the process gas flows.

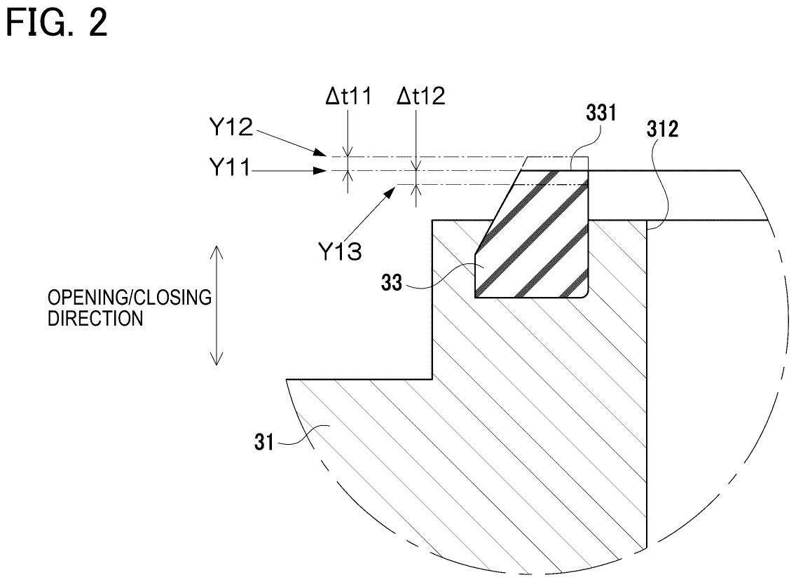

The valve seat 33 is, for example, made of PI (polyimide) or PFA (tetrafluoroethylene perfluoroalkylvinyl ether copolymer) with high thermal resistance. An end face of the valve seat 33 opposing to the valve element 32 is a contact surface 331 (see FIG. 2) that is to be contacted with the valve element 32.

A position Y11 of the contact surface 331 in the opening/closing direction shown in FIG. 2 is a position under a normal temperature. The process gas flowing through the fluid control valve 1 is at an exceptionally high temperature such as 200° C., for example, and thus the valve seat 33 is heated by the process gas and expanded. A position of the contact surface 331 in the opening/closing direction after this expansion is a position indicated with a position Y12. For example, when a material of the valve seat 33 is PFA and a dimension (a thickness dimension) of the valve seat 33 in the opening/closing direction is about 1.5 mm, an expansion amount Δt11 is about 20 to 30 μm.

On the other hand, there are a possibility that the valve seat 33 gets abraded by repetitive contact and separation of the valve element 32 and the valve seat 33 and a possibility that the valve seat 33 is deformed due to creep and others. By the abrasion or the creep, a position of the contact surface 331 in the opening/closing direction becomes a position indicated with a position Y13. A gap of the position Y11 and the position Y13 at this time is defined as a contraction amount Δt12.

The valve element 32 is provided with a main body 321 and a diaphragm 322. The main body 321 is made of stainless steel, for example. The main body 321 is coupled with the rod 9 on an upper end portion and is moved in the opening/closing direction (in an upper and lower direction in the figure) in accordance with reciprocal motion of the drive shaft 62. Then, a lower end face of the main body 321 constitutes a contact surface to be in contact with the valve seat 33.

The diaphragm 322 is a circular disc-like thin film member made of, for example, Ni alloy. The main body 321 and the diaphragm 322 are connected by laser welding, for example. Further, an outer peripheral edge of the diaphragm 322 is fixed to a housing 51. Thus, the diaphragm 322 divides an inside of a cylindrical portion 315 of the body 31 into the valve chamber 311 and its upper portion and repeats elastic deformation in accordance with motion of the main body 321 in the opening/closing direction (in the upper and lower direction in the figure).

### (Control System of Fluid Control Valve)

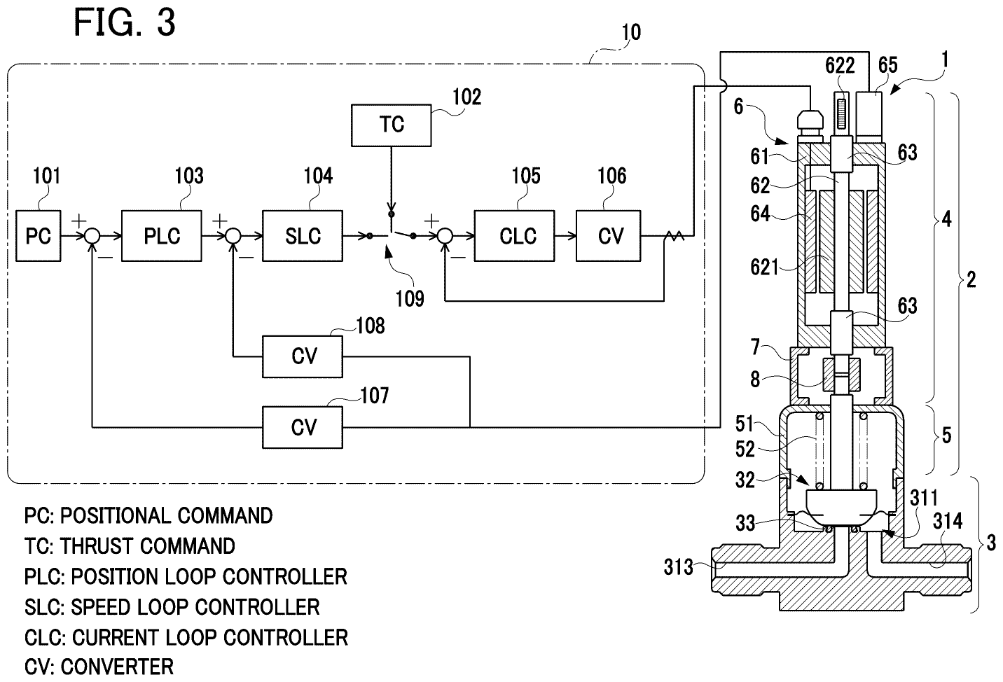

A control system of the fluid control valve 1 is explained with reference to FIG. 3. FIG. 3 is a block diagram of the control system of the fluid control valve 1. A driver 10 for controlling the servomotor 6 is provided with a controller for position control 101, a controller for thrust control 102, a position loop controller 103, a speed loop controller 104, a current loop controller 105, converters 106, 107, 108, and a control switcher 109. The servomotor 6 has a position control mode to control the drive shaft 62 to move to a target position and a thrust control mode to control the drive shaft 62 to obtain a target thrust. The position control mode and the thrust control mode are switchable by the control switcher 109.

Control by the position control mode is performed as follows. First, the controller for position control 101 outputs a positional command to the position loop controller 103 based on the target position of the drive shaft 62.

Then, the position loop controller 103 performs, for example, PD control based on the positional command and a current position of the drive shaft 62 that is fed back from the linear encoder 65, and calculates a speed command. Herein, the current position of the drive shaft 62 that is fed back from the linear encoder 65 is a signal output from the converter 107 based on a pulse number that is output from the linear encoder 65.

Then, the speed loop controller 104 performs, for example, PID control based on the speed command calculated by the positional loop controller 103 and the current speed of the drive shaft 62 that is fed back from the linear encoder 65, and calculates the torque command. Herein, the current speed of the drive shaft 62 that is fed back from the linear encoder 65 represents a signal output from the converter 108 based on a pulse number that is output from the linear encoder 65.

Then, the current loop controller 105 outputs a current command based on the torque command that is calculated by the speed loop controller 104. The current required for the converter 106 is supplied to the servomotor 6 based on this current command, and thereby the position of the drive shaft 62 of the servomotor 6 is controlled.

The control by the thrust control mode is performed as follows. First, the controller for thrust control 102 outputs the thrust command to the current loop controller 105 based on the target thrust of the drive shaft 62. Then, the current loop controller 105 outputs the current command based on the thrust command output from the controller for thrust control 102. The converter 106 supplies the required current to the servomotor 6 based on this current command, and thereby the thrust of the drive shaft 62 of the motor 2 is controlled.

### (Operation of Fluid Control Valve)

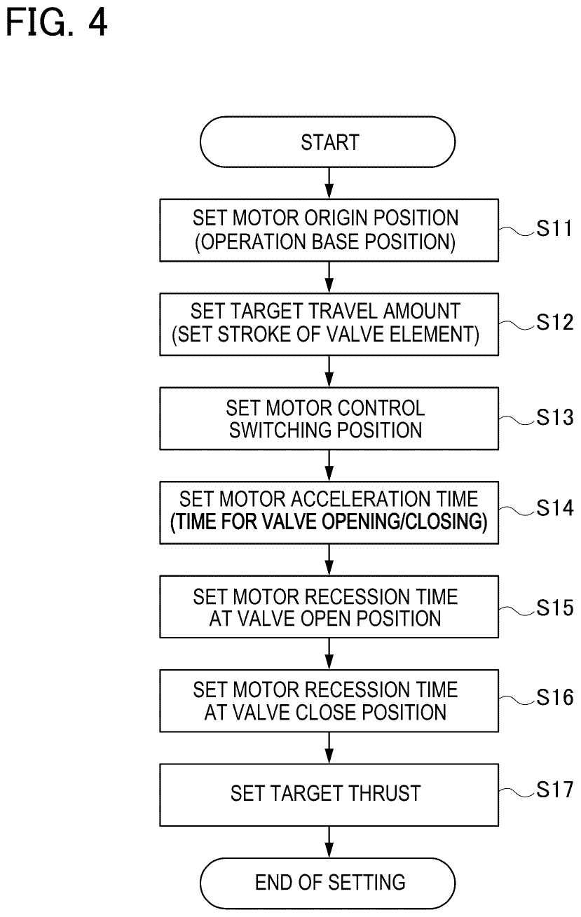

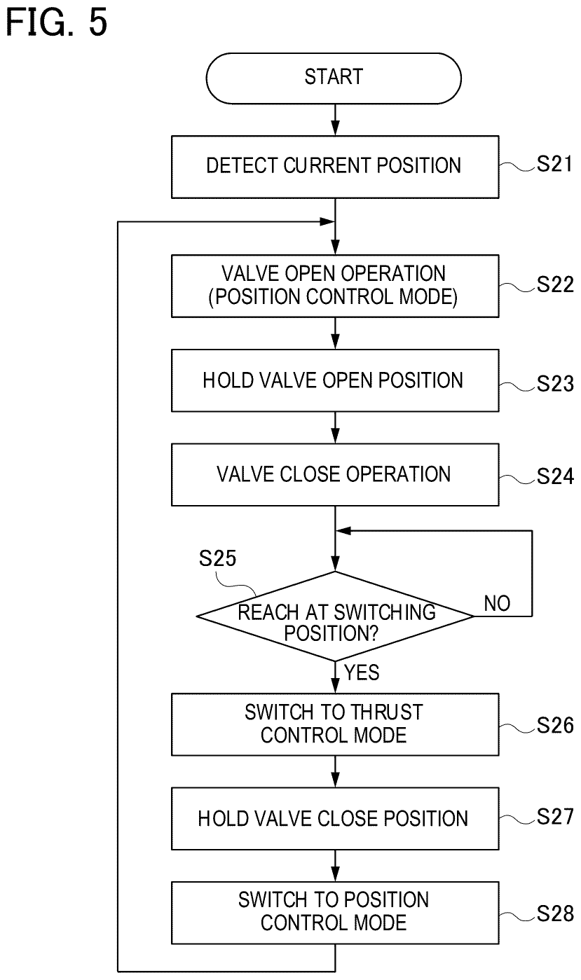

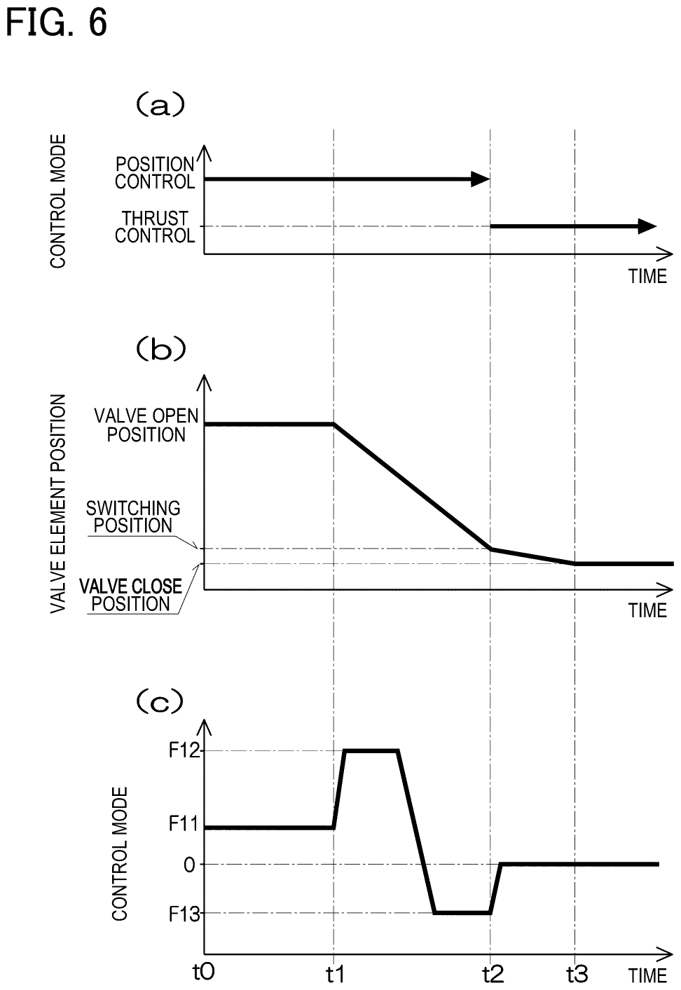

In the above-mentioned control system, the fluid control valve 1 is operated as follows. FIG. 4 is a flow of an initial setting program of the fluid control valve 1. FIG. 5 is a flow of a control program of the fluid control valve 1. FIG. 6 (a) shows a state of a control mode of the servomotor 6 when the valve element 32 is operated from the valve open position to the valve close position. FIG. 6 (b) is a graph showing a position of the valve element 32 when the valve element 32 is operated from the valve open position to the valve close position. FIG. 6 (c) is a graph showing a thrust value of the drive shaft 62 when the valve element 32 is operated from the valve open position to the valve close position.

Before starting use of the fluid control valve 1, parameters (items indicated in S11 to S17 in FIG. 4) necessary for controlling the fluid control valve 1 is performed with initial setting according to the initial setting program. Specific explanation is given below.

Firstly, an origin position of the servomotor 6 is set (S11 in FIG. 4). Specifically, the valve element 32 is brought into contact with the valve seat 33 under a normal temperature. To be specific, the valve element 32 is placed in the valve close position. Then, a position of the drive shaft 62 in this state is set as the origin position. Further, at this time, a position of a contact surface 331 of the valve element 32 to be in contact with the valve element 32 in the opening/closing direction is a position Y11.

Next, a target position is set (S12 in FIG. 4). This target position represents a travel amount of the drive shaft 62 from the origin position to the opening direction. In the position control mode, the controller for position control 101 (see FIG. 3) outputs a positional command based on this target position. The valve element 32 is moved from the valve close position to the opening direction by a travel amount of the drive shaft 62 from the origin position to the opening direction, and thus setting of the target position is synonymous with setting a stroke of the valve element 32 from the valve close position to the valve open position. This target position is appropriately determined based on a flow rate of process gas that is obtained by film forming process in the semiconductor manufacturing process, and others. For example, the stroke is about 1 mm in the present embodiment.

Subsequently, a switching position (one example of a predetermined position) for switching control of the servomotor 6 is set (S13 in FIG. 4). Specifically, when the valve element 32 is to be operated from the valve open position to the valve close position, where to switch control of the servomotor 6 from the position control mode to the thrust control mode in a rage from the valve open position to the valve close position is set.

A switching position is determined based on a thermal expansion amount Δt11 of the valve seat 33 in the opening/closing direction of the valve element 32. Specifically, when the valve seat 33 has the thermal expansion amount Δt11 for example, the switching position is set at a position behind the origin position of the servomotor 6 by the thermal expansion amount Δt11 and an additional several micrometers. This position is a point where the valve element 32 has advanced by 90 to 95% from the valve open position to the closing direction in the stroke (for example, 1 mm) from the valve open position to the valve close position of the valve element 32.

Subsequently, acceleration time of the servomotor 6 is set (S14 in FIG. 4). This setting is to set a period of time required for the drive shaft 62 to move from the origin position to the target position. This setting is synonymous with setting a period of time for the valve element 32 to travel between the valve open position and the valve close position.

Subsequently, a recession time of the servomotor 6 at the valve open position is set (S15 in FIG. 4). This setting is to set a period of time for maintaining the valve open state of the valve element 32 after the valve element 32 reaches the valve open position.

Subsequently, the recession time of the servomotor 6 at the valve close position is set (S16 in FIG. 14). This setting is to set a period of time for maintaining the valve closed state after the valve element 32 reaches the valve close position. Each period of time set in each of S14 to S16 in FIG. 4 as mentioned above is appropriately set in accordance with a cycle time of opening and closing operation that is required in the film forming step in the semiconductor manufacturing process.

Subsequently, a target thrust is set (S17 in FIG. 4). This setting is to set the thrust for driving the drive shaft 62 when the servomotor 6 is controlled by the thrust control mode. Herein, the target thrust is set as zero. When the setting of the target thrust is completed, initial setting of the parameters is completed. Herein, an order of setting the respective parameters (S11 to S17 in FIG. 4) is not limited to the above order. Further, the step S17 in FIG. 4 may be omitted and the target thrust may have been set as zero in advance.

Opening and closing operation of the fluid control valve 1 is performed by a control program explained below.

Firstly, when operation of the fluid control valve 1 is started, the linear encoder 65 detects a current position of the drive shaft 62 (S21 in FIG. 5). The current position of the drive shaft 62 specifically represents a current position of the valve element 32. The valve element 32 is continuously urged to the closing direction by the spring 52, and therefore, the valve element 32 is in the valve close position at the timing of starting operation of the fluid control valve 1. Accordingly, herein, the current position is detected to be at the origin position.

Subsequently, the valve opening operation is performed (S22 in FIG. 5). Namely, the valve element 32 is driven to move to the valve open position. This is performed under the position control mode, and thus performed based on the target position set by the initial setting (see S12 in FIG. 4). In the present embodiment, the stroke is set as 1 mm, and thus the valve element 32 is moved by 1 mm from the origin position to the opening direction. A travel speed at this time is based on the acceleration time of the servomotor 6 that has been set by the initial setting (see S14 in FIG. 4).

Herein, a time point to in FIG. 6 is a point of time when the valve element 32 has reached the valve open position. As shown in FIG. 6 (a), at the time point to, the control mode of the servomotor 6 is the position control mode. Further, as shown in FIG. 6 (b), the valve element 32 is placed at the valve open position. Further, the thrust of the drive shaft 62 indicates a value (F11) larger than zero. The thrust is generated in the drive shaft 62 because the position of the drive shaft 62 is maintained at the valve open position against the urging force of the spring 52. Herein, whether the valve element 32 has reached the valve open position is monitored by checking whether a change amount of the current position of the drive shaft 62 is within a certain range of a deviation pulse. When the change amount is within the subject range, the valve element 32 is determined to have reached the valve open position.

Subsequently, after the valve element 32 has moved to the valve open position, the valve element 32 is retained in the valve open position (S23 in FIG. 5). This retention period of time continues based on the recession time (see S15 in FIG. 4) of the servomotor 6 at the valve open position that has been set by the initial setting.

Herein, a term from the time point t0 to a time point t1 in FIG. 6 corresponds to this recession time. During the term from the time point t0 to the time point t1, the valve element 32 is maintained to be at the valve open position by the position control mode (see FIGS. 6 (a) and (b)). The thrust generated in the drive shaft 62 also remains constant during the time point t0 to the time point t1 (see FIG. 6 (c)).

After elapse of the above recession time, the valve closing operation is subsequently performed (S24 in FIG. 5). This operation is performed under the position control mode, and the drive shaft 62 of the servomotor 6 is controlled to move toward the origin position, so that the valve element 32 is driven toward the valve close position. A travel speed at this time is based on the acceleration time (see S14 in FIG. 4) of the servomotor 6 that has been set by the initial setting.

Herein, the time point t1 in FIG. 6 represents a time point when the valve closing operation is started. While the position control mode is maintained from the time point t1, the valve element 32 starts its operation toward the valve close position (see FIGS. 6 (a) and (b)). Then, the thrust of the drive shaft 62 indicates the maximum value (F12) directly after starting the valve closing operation. This is for the purpose of abruptly accelerating the drive shaft 62 in the closing direction. Then, as the valve element 32 approaches the valve close position, the thrust works in the opening direction to brake the drive shaft 62. Accordingly, in FIG. 6 (c), the thrust decreases to a minus value (F13).

Subsequently, when the valve closing operation is started, whether the drive shaft 62 has reached a switching position for controlling the servomotor 6 is monitored (S25 in FIG. 5). The switching position for controlling the servomotor 6 represents a position at which the control of the servomotor 6 is switched from the position control mode to the thrust control mode that has been set by the initial setting (see S13 in FIG. 4). Until reaching the switching position, the drive shaft 62 of the servomotor 6 continues to be controlled to move to the origin position by the position control mode (S25: NO). Then, when the drive shaft 62 has reached the switching position (S25: YES), switching to the thrust control mode is performed (S26 in FIG. 5). This switching is performed by switching the control switcher 109 (see FIG. 3).

After the mode is switched to the thrust control mode, the servomotor 6 is controlled based on the target thrust. The target thrust is a parameter that is set by the initial setting (see S17 in FIG. 4), and herein, the target thrust is set as zero. Accordingly, when the mode is switched to the thrust control mode, supply of electric current to the servomotor 6 from the converter 106 (see FIG. 3) is recessed. Then, the valve element 32 is moved to a position (the valve close position) where the valve element 32 is brought into contact with the valve seat 33 only by the urging force of the spring 52.

Under the normal temperature, the origin position of the servomotor 6 corresponds to the valve close position, but when the valve seat 33 is expanded, the valve close position is displaced from the origin position in the opening direction by the amount of the thermal expansion amount Δt11 (see FIG. 2). Namely, the valve element 32 and the valve seat 33 come to contact with each other before the servomotor 6 reaches the origin position. However, the valve element 32 is driven only by the urging force of the spring 52 from the switching position, and thus the servomotor 6 would not try to return to the origin thereafter even if the valve seat 33 is expanded, and the valve element 32 and the valve seat 33 come to contact before the servomotor 6 reaches the origin position. Accordingly, the servomotor 6 is free from high load and breakage in the servomotor 6 such as burn damage of the coil 64 can be prevented.

Further, the switching position from the position control mode to the thrust control mode is determined to be a position where the valve element 32 advances from the valve open position to the valve close position by 90 to 95% in the stroke from the valve open position to the valve close position of the valve element 32. Accordingly, the responsivity in driving the valve element 32 from the valve open position to the valve close position is improved. The fluid control valve 1 placed in a gas supply system of a semiconductor manufacturing device is small-sized, and thus the urging force of the spring 52 is lower than that of an ordinary air-operated-type valve. Therefore, in order to improve the responsivity, it is preferable to make the switching position as close as possible to the valve seat 33 and to reduce a range of relying only on the urging force of the spring 52 from the valve open position to the valve close position as narrow as possible. By setting the switching position as above, the valve element 32 is driven under the position control mode of the servomotor 6 directly before contacting with the expanded valve seat 33, so that the valve can be closed with high responsivity.

On the other hand, when the valve seat 33 is abraded or creeps and a position of the contact surface 331 is lowered, the valve close position is displaced to the closing direction from the origin position by the amount of its contraction amount Δt2 (see FIG. 2). Namely, even when the servomotor 6 reaches the origin position, the valve element 32 fails to be in contact with the valve seat 33. However, the valve element 32 is driven only by the urging force of the spring 52 from the switching position, and therefore the valve element 32 is assuredly driven to the valve close position to be in contact with the valve seat 33 without stopping at the origin position even after the servomotor 6 has reached the origin position. Therefore, occurrence of fluid leakage due to sealing failure can be prevented.

Herein, the time point t2 in FIG. 6 is the timing when the valve element 32 has reached the switching position, and also the timing when control of the servomotor 6 has been switched from the position control mode to the thrust control mode. When the mode is switched to the thrust control mode, the thrust of the drive shaft 62 becomes zero based on the set target thrust. Then, the travel speed of the valve element 32 is decelerated since the time point t2 at which the mode has been switched to the thrust control mode (an inclination of a graph in FIG. 6 (b) becomes gentle). This is because the valve element 32 is moved only by the urging force of the spring 52. Then, the time point t3 in FIG. 6 is the timing when the valve element 32 has reached the valve close position. Herein, whether the valve element 32 has reached the valve close position is monitored by confirming whether a change amount of the current position of the drive shaft 62 is within a range of the deviation pulse. When the change amount is within the range, the valve element 32 is determined to have reached the valve close position.

Subsequently, when the valve element 32 has reached the valve close position, the valve element 32 is held at the valve close position (S27 in FIG. 5). A period of time for this holding is carried out based on the recession time of the servomotor 6 at the valve close position (see S16 in FIG. 4) that has been set by the initial setting. While the valve element 32 is held in the valve close position, the servomotor 6 is controlled by the thrust control mode with the target thrust of zero. In other words, the servomotor 6 is not subjected to any load and the valve closed state is maintained only by the urging force of the spring 52. Thereby, the load applied to the servomotor 6 can be reduced and a lifespan can be extended. Further, for example, even when the fluid control valve 1 gets broken down or electric supply to the fluid control valve 1 is shut off due to power outage and others, the valve closed state is maintained only by the urging force of the spring 52, achieving high safety in view of fail safe.

As the above-mentioned recession time has elapsed, subsequently, the mode is switched to the position control mode (S28 in FIG. 5), and thereafter, the valve closing operation under the position control mode is performed (S24 in FIG. 5). As mentioned above, by repeating the processes of S22 to S28 in FIG. 5, opening and closing operation of the fluid control valve 1 is performed.

As explained above, the fluid control valve 1 according to the present embodiment is configured as (1) being provided with a motor (for example, the servomotor 6), the valve element 32, the valve seat 33, and a passage (a series of passages constituted of the input passage 313, the valve chamber 311, and the output passage 314), and configured to perform controlling of a control fluid (for example, process gas) to flow through the passage by moving the valve element 32 with the motor (the servomotor 6) between the valve open position at which the valve element 32 is separated from the valve seat 33 and a valve close position at which the valve element 32 is contacted with the valve seat 33. The fluid control valve 1 is provided with an elastic member (for example, the spring 52) to apply an urging force to the valve element 32 in a closing direction, the motor (the servomotor 6) is provided with a drive shaft 62 to operate the valve element 32, a position control mode to control the drive shaft 62 to move to a target position and a thrust control mode to control the drive shaft 62 to obtain a target thrust are provided, and while the valve element moves 32 moves from the valve open position to the valve close position, the fluid control valve 1 is provided with a control program configured to control the motor (the servomotor 6) with the position control mode until the valve element 32 reaches a predetermined position (a switching position) before reaching the valve close position from the valve open position and to switch control of the motor (the servomotor 6) from the position control mode to the thrust control mode with the target thrust of zero to bring the valve element 32 to reach the valve close position from the predetermined position (the switching position) only by the urging force.

According to the fluid control valve 1 described in (1), when the valve element 32 is operated from the valve open position to the valve close position, the motor (the servomotor 6) is controlled by the position control mode until the valve element 32 reaches the predetermined position from the valve open position before reaching the valve close position. Control of the motor (the servomotor 6) is switched from the position control mode to the thrust control mode in which the target thrust is set as zero at the predetermined position so that the valve element re is controlled to reach the valve close position only by the urging force of the elastic member. Namely, the valve element 32 is driven only by the urging force of the elastic member (the spring 52) from the predetermined position (the switching position) to the valve close position. Accordingly, even when the valve element 32 and the valve seat 33 are brought into contact with each other before the motor (the servomotor 6) reaches the origin position due to expansion of the valve seat 33, the motor (the servomotor 6) would not return to the original position thereafter. Therefore, no high load is applied to the motor (the servomotor 6), and thus breakdown of the motor (the servomotor 6) such as burn damage of the motor coil 4 can be prevented.

Further, even when the valve element 32 and the valve seat 33 fail to be in contact after the motor (the servomotor 6) has reached the origin position due to decrease in a size of the valve seat 33 that gets abraded, the valve element 32 is assuredly driven to the valve close position to be in contact with the valve seat 33 without stopping at the origin position since the valve element 32 is driven only by the urging force of the elastic member (the spring 52) from the predetermined position (the switching position). Therefore, occurrence of fluid leakage due to sealing failure can be prevented.

(2) In the fluid control valve 1 described in (1), preferably, the control program (steps S21 to S28 in FIG. 5) is configured to maintain a state in which the valve element 32 is at the valve close position after the valve element 32 reaches the valve close position by the thrust control mode with the target thrust of zero.

According to the fluid control valve 1 described in (2), a case of maintaining the valve closed state, namely, a state where the valve element 32 is in the valve close position is maintained by the thrust control mode with the target thrust of zero. Specifically, the motor (the servomotor 6) is not applied with any load but applied only with the urging force of the elastic member (the spring 52) to maintain the valve closed state. Thereby, the load applied to the motor (the servomotor 6) is reduced and the lifespan can be extended. Furthermore, for example, even when the fluid control valve 1 gets broken down or the electric supply to the fluid control valve 1 is shut off due to power outage and others, the valve closed state can be maintained only by the urging force of the elastic member (the spring 52), thus achieving high safety in view of fail safe.

(3) In the fluid control valve 1 described in (1) or (2), preferably, the predetermined position (the switching position) is determined based on a thermal expansion amount Δt11 of the valve seat 33 in an opening/closing direction of the valve element 32.

In order to improve responsivity while the valve element 32 is driven from the valve open position to the valve close position, it is preferable to arrange the predetermined position (the switching position) as close as possible to the valve seat 33 so that a range of relying only on the urging force of the elastic member (the spring 52) from the valve open position to the valve close position is made as narrow as possible. Accordingly, the predetermined position (the switching position) is determined based on the thermal expansion amount Δt11 of the valve seat 33 in the opening/closing direction of the valve element 32. Specifically, for example, the predetermined position is set in a position behind the origin position of the motor (the servomotor 6) by the amount Δt11 and an additional several micrometers. This position is a position at which the valve element 32 is moved ahead from the valve open position to the closing direction by 90 to 95% in the stroke of the valve element 32 from the valve open position to the valve close position. By setting the predetermined position (the switching position) as mentioned above, the valve element 32 is driven by the position control mode of the motor (the servomotor 6) by the position directly before contacting with the expanded valve seat 33, so that the valve can be closed with high responsivity.

The above embodiment is only an illustration and gives no limitation to the present invention. Accordingly, the present invention can naturally be made with various improvements and modifications without departing from the scope of the subject matter. For example, opening and closing operation of the fluid control valve 1 according to the present embodiment is performed by bringing a lower end face of the main body 321 of the valve element 32 into or out of contact with the valve seat 33. Alternatively, as disclosed in JP2017-223318A, a fluid control valve may be configured that opening and closing operation is performed by bringing a diaphragm into or out of contact with a valve seat.

### REFERENCE SIGNS LIST

1 Fluid control valve
6 Servomotor (one example of a motor)
32 Valve element
33 Valve seat
52 Spring (one example of an elastic member)
62 Drive shaft

1. A fluid control valve
provided with a motor, a valve element, a valve seat, and a passage, and
configured to perform controlling of a control fluid to flow through the passage by moving the valve element with the motor between a valve open position at which the valve element is separated from the valve seat and a valve close position at which the valve element is contacted with the valve seat, wherein
the fluid control valve is provided with an elastic member to apply an urging force to the valve element in a closing direction,
the motor is provided with a drive shaft to operate the valve element,
a position control mode to control the drive shaft to move to a target position and a thrust control mode to control the drive shaft to obtain a target thrust are provided, and
while the valve element moves from the valve open position to the valve close position, the fluid control valve is provided with a control program configured to control the motor with the position control mode until the valve element reaches a predetermined position before reaching the valve close position from the valve open position and to switch control of the motor from the position control mode to the thrust control mode with the target thrust of zero to bring the valve element to reach the valve close position from the predetermined position only by the urging force.

2. The fluid control valve according to claim 1, wherein
the control program is configured to maintain a state in which the valve element is at the valve close position after the valve element reaches the valve close position by the thrust control mode with the target thrust of zero.

3. The fluid control valve according to claim 1, wherein the predetermined position is determined based on a thermal expansion amount of the valve seat in an opening/closing direction of the valve element.

4. The fluid control valve according to claim 2, wherein the predetermined position is determined based on a thermal expansion amount of the valve seat in an opening/closing direction of the valve element.
